(19) United States
(12) Patent Application Publication
(10) Pub. No.: US 2026/0188093 A1
(43) Pub. Date: Jul. 2, 2026

(54) METHOD OF DETECTING FIRE IN BATTERIES USING CLOUD SERVICES

(71) Applicant: SAMSUNG SDI CO., LTD., Yongin-si (KR)

(72) Inventor: Jihoon LEE, Yongin-si (KR)

(21) Appl. No.: 19/381,241

(22) Filed: Nov. 6, 2025

(30) Foreign Application Priority Data
Dec. 26, 2024 (KR) 10-2024-0197788

(51) Int. Cl. G08B 17/06; G01R 19/165; G01R 31/367; G01R 31/371; G01R 31/3842; G01R 31/396; H01M 10/42; H01M 10/48

(52) U.S. Cl. CPC G08B 17/06; G01R 19/16542; G01R 31/367; G01R 31/371; G01R 31/3842; G01R 31/396; H01M 10/425; H01M 10/486; H01M 2010/4271; H01M 2010/4278

(57) ABSTRACT

A method of detecting fire in ESSs includes receiving battery status data from battery management systems via a cloud server. The received battery status data is analyzed to determine whether a fire occurs. It is possible to detect whether a fire has occurred in an ESS without a separate fire sensor in the ESS.

### CROSS-REFERENCE TO RELATED APPLICATION

The present application claims the benefit of priority to Korean Patent Application No. 10-2024-0197788, filed on Dec. 26, 2024, in the Korean Intellectual Property Office, the entire disclosure of which is incorporated herein by reference.

### BACKGROUND

### 1. Technical Field

The present disclosure relates to a method of detecting fire in batteries using cloud services.

### 2. Related Art

Energy storage systems (ESSs) are systems that are able to store surplus electricity or electricity produced, for example, by renewable energy sources. The ESSs enable smooth control of power supply and demand by storing idle power during times of low electricity demand and then supplying the powers during times of high electricity demand.

In some situations, a fire may start in an ESS. If the fire is not extinguished in its early stages, it can be difficult to extinguish the fire. Thus, it is necessary to detect whether a fire has occurred in ESSs at an early stage.

Whether a fire has occurred in ESSs may be detected using sensors such as smoke detectors, but it is difficult to recognize the occurrence of fire with if the batteries of the smoke detectors are discharged or broken. And, as ESSs are often operated unmanned in remote locations, it is difficult to check whether there is a fire at the ESS, particularly during the early stages of the fire.

The above disclosed in this background section is for enhancement of understanding of the background of the present disclosure. It may contain information that does not constitute prior art.

### SUMMARY

An object of the present disclosure is to provide a method for early detection of a fire in an ESS or battery pack. Another object of the present disclosure is to provide a method for early detection of a fire even when a fire sensor is not installed at the site of the fire.

In accordance with an aspect of the present disclosure, there is provided a method of detecting fire in ESSs that includes receiving battery status data from battery management systems via a server and analyzing the received battery status data to determine whether a fire occurs in one of the EESs.

In the analyzing the received battery status data, the fire is determined to occur if a cell voltage drops over a predetermined period of time, a voltage deviation between cells is maintained over a predetermined period of time, and a minimum cell voltage within a rack is lower than a threshold voltage.

In the analyzing the received battery status data, the fire is determined to occur if the following three conditions are all satisfied: (i) a cell voltage drops over a predetermined period of time; (ii) a voltage deviation between cells is maintained over a predetermined period of time; and (iii) a minimum cell voltage within a rack is lower than a threshold voltage, and at least one of the following five conditions is satisfied: (i) an alarm that an in-module temperature is maintained above a certain value is generated; (ii) a protective action is performed because the in-module temperature is maintained above the certain value; (iii) an alarm that a communication error occurs between a rack BMS and a module BMS is generated; (iv) a protective action is performed because the communication error occurs between the rack BMS and the module BMS; and (v) a module BMS PCB temperature is maintained above a certain value.

In the analyzing the received battery status data, the fire is determined to occur if at least two of the following three conditions are satisfied: (i) a cell voltage

drops over a predetermined period of time, (ii) a voltage deviation between cells is maintained over a predetermined period of time, and (iii) a minimum cell voltage within a rack is lower than a threshold voltage.

In the analyzing the received battery status data, the fire is determined to occur if at least two of the following three conditions are satisfied: (i) a cell voltage

drops over a predetermined period of time; (ii) a voltage deviation between cells is maintained over a predetermined period of time; and (iii) a minimum cell voltage within a rack is lower than a threshold voltage, and (iv) at least one of the following five conditions is satisfied: (iv-i) an alarm that an in-module temperature is maintained above a certain value is generated; (iv-ii) a protective action is performed because the in-module temperature is maintained above the certain value; (iv-iii) an alarm that a communication error occurs between a rack BMS and a module BMS is generated; (iv-iv) a protective action is performed because the communication error occurs between the rack BMS and the module BMS; and (iv-v) a module BMS PCB temperature is maintained above a certain value.

In the analyzing the received battery status data, the fire is determined to occur if a minimum cell voltage within a rack is lower than a threshold voltage, a current measured in the rack is lower than a threshold current, a maximum module temperature within the rack is higher than a threshold temperature, and the minimum cell voltage within the rack being lower than the threshold voltage and the maximum module temperature within the rack being higher than the threshold temperature occur in one module.

The method for detecting fire in ESSs may further include providing a notification that a fire event occurs when it is determined that the fire occurs.

The server may be a cloud server.

In accordance with another aspect of the present disclosure, there is provided a method for detecting fire in battery packs, which includes receiving battery status data from battery management systems via a server, and analyzing the received battery status data to determine whether a fire occurs in one of the battery packs.

In the analyzing the received battery status data, the fire is determined to occur if a cell voltage drops over a predetermined period of time, a voltage deviation between cells is maintained over a predetermined period of time, and a minimum cell voltage within a battery pack is lower than a threshold voltage.

In the analyzing the received battery status data, the fire is determined to occur if the following three conditions are all satisfied: (i) a cell voltage drops over a predetermined period of time; (ii) a voltage deviation between cells is maintained over a predetermined period of time; and (iii) a minimum cell voltage within a battery pack is lower than a threshold voltage, and at least one of the following five conditions is satisfied: (i) an alarm that an in-module temperature is maintained above a certain value is

generated; (ii) a protective action is performed because the in-module temperature is maintained above the certain value; (iii) an alarm that a communication error occurs between a battery pack BMS and a module BMS is generated; (iv) a protective action is performed because the communication error occurs between the battery pack BMS and the module BMS; and (v) a module BMS PCB temperature is maintained above a certain value.

In the analyzing the received battery status data, the fire is determined to occur if at least two of the following three conditions are satisfied: (i) a cell voltage drops over a predetermined period of time, (ii) a voltage deviation between cells is maintained over a predetermined period of time, and (iii) a minimum cell voltage within a battery pack is lower than a threshold voltage.

In the analyzing the received battery status data, the fire is determined to occur if at least two of the following three conditions are satisfied: (i) a cell voltage drops over a predetermined period of time, (ii) a voltage deviation between cells is maintained over a predetermined period of time, (iii) a minimum cell voltage within a battery pack is lower than a threshold voltage; and (iv) at least one of the following five conditions is satisfied: (iv-i) an alarm that an in-module temperature is maintained above a certain value is generated; (iv-ii) a protective action is performed because the in-module temperature is maintained above the certain value; (iv-iii) an alarm that a communication error occurs between a battery pack BMS and a module BMS is generated; (iv-iv) a protective action is performed because the communication error occurs between the battery pack BMS and the module BMS; and (iv-v) a module BMS PCB temperature is maintained above a certain value.

In the analyzing the received battery status data, the fire is determined occur if a minimum cell voltage within a battery pack is lower than a threshold voltage, a current measured in the battery pack is lower than a threshold current, a maximum module temperature within the battery pack is higher than a threshold temperature, and the minimum cell voltage within the battery pack being lower than the threshold voltage and the maximum module temperature within the battery pack being higher than the threshold temperature occur in one module.

The method for detecting fire in battery packs may further include providing a notification that a fire event occurs when it is determined that the fire occurs.

The server may be a cloud server.

### BRIEF DESCRIPTION OF THE DRAWINGS

The drawings illustrate preferred embodiments of the present disclosure and help to further understand the technical spirit of the present disclosure. The present disclosure should not be construed as being limited to the embodiments depicted in the drawings.

FIG. 1 illustrates an electrode assembly of a secondary battery;

FIG. 2 illustrates a pouch-type secondary battery;

FIG. 3 is a top perspective view of an exterior of a prismatic battery;

FIG. 4 is a cross-sectional view of a cylindrical secondary battery;

FIG. 5 is a conceptual diagram of a method of detecting fire in ESSs using cloud services according to the present disclosure;

FIG. 6 is a flow diagram of a procedure for determining whether there is a fire event according to an embodiment of the present disclosure;

FIG. 7 is a flow diagram of a fire event occurrence determination algorithm according to the embodiment of the present disclosure;

FIG. 8 is a flow diagram of a fire event occurrence determination algorithm according to another embodiment of the present disclosure;

FIG. 9 is a flow diagram of a procedure for determining whether there is a fire event according to another embodiment of the present disclosure;

FIG. 10 is a block diagram illustrating a computer system for implementing a method according to an embodiment of the present disclosure.

FIG. 11 is a view of a secondary battery module in which secondary batteries are arranged according to one or more embodiments of the present disclosure;

FIG. 12 is a view of a secondary battery pack including the secondary battery module illustrated in FIG. 11; and

FIG. 13 is a conceptual view of a vehicle including the secondary battery pack illustrated in FIG. 12.

### DETAILED DESCRIPTION

Exemplary embodiments of the present disclosure will be described below in detail with reference to the accompanying drawings. Prior to the description, it is noted that the terms or words used in this specification and claims should not be construed as being limited to common or dictionary meanings but instead should be understood to have meanings and concepts in agreement with the spirit of the present disclosure based on the principle that an inventor can define the concept of each term suitably in order to describe his/her own invention in the best way possible. Accordingly, since the embodiments described in this specification and the configurations illustrated in the drawings are only an example of the present disclosure and they do not cover all the technical ideas of the present disclosure, it should be understood that various changes and modifications may be made at the time of filing this application.

It will be further understood that the terms “comprises/includes” and/or “comprising/including” when used herein, specify the presence of stated features, integers, steps, operations, elements, components, and/or groups thereof, but do not preclude the presence or addition of one or more other features, integers, steps, operations, elements, components, and/or groups thereof.

In order to facilitate understanding of the present disclosure, the accompanying drawings are not drawn to scale and the dimensions of some components may be exaggerated. It should be noted that the same reference numerals are designated to the same components in different embodiments.

Reference to two compared elements, features, etc. as being “the same” means that they are “substantially the same”. Therefore, the phrase “substantially the same” may include a deviation that is considered low in the art, for example, a deviation of 5% or less. The uniformity of any parameter in a given region may mean that it is uniform from an average perspective.

Although the terms such as “first” and/or “second” are used to describe various components, these components are not limited by these terms, of course. These terms are only used to distinguish one component from another component. Thus, unless specifically stated to the contrary, a first component may be termed a second component without departing from the teachings of exemplary embodiments.

Throughout the specification, unless otherwise stated, each element may be singular or plural.

Arrangement of any component “above (or below)” or “on (or under)” a component may mean that any component is disposed in contact with the upper (or lower) surface of the component, as well as that other components may be interposed between the element and any element disposed on (or under) the element.

It will be understood that, when a component is referred to as being “connected”, “coupled”, or “joined” to another component, not only can it be directly “connected”, “coupled”, or “joined” to the other element, but also can it be indirectly “connected”, “coupled”, or “joined” to the other element with other elements interposed therebetween.

As used herein, the term “and/or” includes any and all combinations of one or more of the associate listed items. The use of “may” when describing embodiments of the present disclosure relates to “one or more embodiments of the present disclosure”. Expressions such as “at least one” and “one or more” preceding a list of elements modify the entire list of elements and do not modify the individual elements in the list.

Throughout the specification, when “A and/or B” is stated, it means A, B, or A and B, unless otherwise stated. In addition, when “C to D” is stated, it means C or more and D or less, unless specifically stated to the contrary.

When the phrase such as “at least one of A, B, and C”, “at least one of A, B, or C”, “at least one selected from the group of A, B, and C”, or “at least one selected from among A, B, and C” is used to designate a list of elements A, B, and C, the phrase may refer to any and all suitable combinations.

The term “use” may be considered synonymous with the term “utilize”. As used herein, the terms “substantially,” “about,” and similar terms are used as terms of approximation rather than as terms of degree, and are intended to account for inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Accordingly, a first element, component, region, layer, or section discussed below may be termed a second element, component, region, layer, or section without departing from the teachings of exemplary embodiments.

For ease of explanation in describing the relationship of one element or feature to another element(s) or feature(s) as illustrated in the drawings, spatially relative terms such as “beneath”, “below”, “lower”, “above”, and “upper” may be used herein. It will be understood that spatially relative positions are intended to encompass different directions of the device in use or operation in addition to the direction depicted in the drawings. For example, if the device in the drawings is turned over, any element described as being “below” or “beneath” another element would then be oriented “above” or “over” another element. Therefore, the term “below” may encompass both upward and downward directions.

The terminology used herein is for the purpose of describing embodiments of the present disclosure and is not intended to limit the present disclosure.

A battery pack according to one or more embodiments includes at least one battery module and a pack housing having an accommodation space in which the at least one battery module is accommodated.

The battery module may include a plurality of battery cells and a module housing. The battery cells may be accommodated inside the module housing in a stacked form (or stacked arrangement or configuration). Each battery cell may have a positive electrode terminal and a negative electrode terminal and may be a cylindrical type, a prismatic type, or a pouch type according to the shape of battery. In the present specification, a battery cell may also be referred to as a secondary battery, a battery, or a cell.

In the battery pack, one cell stack may constitute one module stacked in place of the battery module. The cell stack may be accommodated in an accommodation space of the pack housing or may be accommodated in an accommodation space partitioned by a frame, a partition wall, etc.

The battery cell may generate a large amount of heat during charging/discharging. The generated heat may be accumulated in the battery cell, thereby accelerating the deterioration of the battery cell. Accordingly, the battery pack may further include a cooling member to remove the generated heat and thereby suppress deterioration of the battery cell. The cooling member may be provided at the bottom of the accommodation space at where the battery cell is provided but is not limited thereto and may be provided at the top or side depending on the battery pack.

The battery cell may be configured such that exhaust gas generated inside the battery cell under abnormal operating conditions, also known as thermal runaway or thermal events, is discharged to the outside of the battery cell. The battery pack or the battery module may include an exhaust port for discharging the gas to prevent or reduce damage to the battery pack or module by the exhaust gas.

The battery pack may include a battery and a battery management system (BMS) for managing the battery. The battery management system may include a detection device, a balancing device, and a control device. The battery module may include a plurality of cells connected to each other in series and/or parallel. The battery modules may be connected to each other in series and/or in parallel.

The detection device may detect a state of a battery (e.g., voltage, current, temperature, etc.) to output state information indicating the state of the battery. The detection device may detect the voltage of each cell constituting the battery or of each battery module. The detection device may detect current flowing through each battery module constituting the battery cell or the battery pack. The detection device may also detect the temperature of a cell and/or module on at least one point of the battery and/or an ambient temperature.

The balancing device may perform a balancing operation of a battery module and/or cells constituting the battery module. The control device may receive state information (e.g., voltage, current, temperature, etc.) of the battery module from the detection device. The control device may monitor and calculate the state of the battery module (e.g., voltage, current, temperature, state of charge (SOC), life span (state of health (SOH)), etc.) based on the state information received from the detection device. In addition, based on the monitored state information, the control device may perform a control function (e.g., temperature control, balancing control, charge/discharge control, etc.) and a protection function (e.g., over-discharge, over-charge, over-current protection, short circuit, fire extinguishing function, etc.). In addition, the control device may perform a wired or wireless communication function with an external device of the battery pack (e.g., a higher level controller or vehicle, charger, power conversion system, etc.).

The control device may control charging/discharging operation and protection operation of the battery. To this end, the control device may include a charge/discharge control unit, a balancing control unit, and/or a protection unit.

The battery management system is a system that monitors the battery state and performs diagnosis and control, communication, and protection functions, and may calculate the charge/discharge state, calculate battery life or state of health (SOH), cut off, as necessary, battery power (e.g., relay control), control thermal management (e.g., cooling, heating, etc.), perform a high-voltage interlock function, and/or may detect and/or calculate insulation and short circuit conditions.

A relay may be a mechanical contactor that is turned on and off by the magnetic force of a coil or a semiconductor switch, such as a metal oxide semiconductor field effect transistor (MOSFET).

The relay control has a function of cutting off the power supply from the battery if (or when) a problem occurs in the vehicle and the battery system and may include one or more relays and pre-charge relays at the positive terminal and the negative terminal, respectively.

In the pre-charge control, there is a risk of inrush current occurring in the high-voltage capacitor on the input side of the inverter when the battery load is connected. Thus, to prevent inrush current when starting a vehicle, the pre-charge relay may be operated before connecting the main relay and the pre-charge resistor may be connected.

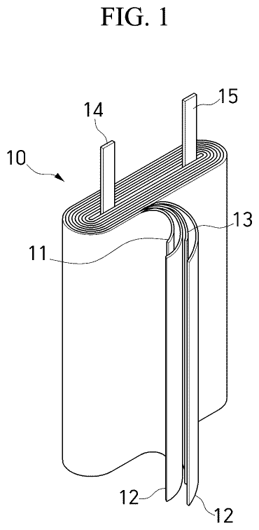

FIG. 1 shows an electrode assembly of a secondary battery.

An electrode assembly 10 may be formed by winding or stacking a stack of a first electrode plate 11, a separator 12, and a second electrode plate 13, which are formed as thin plates or films. When the electrode assembly 10 is a wound stack, a winding axis may be parallel to the longitudinal direction (e.g., the y direction) of the case. In other embodiments, the electrode assembly 10 may be a stack type rather than a winding type, and the shape of the electrode assembly 10 is not limited in the present disclosure. In addition, the electrode assembly 10 may be a Z-stack electrode assembly in which a positive electrode plate and a negative electrode plate are provided to both sides of a separator, which is then bent into a Z-stack. In addition, one or more electrode assemblies may be stacked such that long sides of the electrode assemblies are adjacent to each other and accommodated in the case, and the number of electrode assemblies in the case is not limited in the present disclosure. The first electrode plate 11 of the electrode assembly may act as a negative electrode, and the second electrode plate 13 may act as a positive electrode. Of course, the reverse is also possible.

The first electrode plate 11 may be formed by applying a first electrode active material, such as graphite or carbon, to a first electrode current collector formed of a metal foil, such as copper, a copper alloy, nickel, or a nickel alloy. The first electrode tab 14 may be connected to an external first terminal (not shown). In some embodiments, when the first electrode plate 11 is made, the first electrode tab 14 may be formed by being cut to protrude to one side of the electrode assembly 10, or the first electrode tab 14 may protrude to one side of the electrode assembly 10 more than (e.g., farther than or beyond) the separator 12 without being separately cut.

The second electrode plate 13 may be formed by applying a second electrode active material, such as a transition metal oxide, on a second electrode current collector formed of a metal foil, such as aluminum or an aluminum alloy. The second electrode plate 13 may include a second electrode tab 15 (e.g., a second uncoated portion) that is a region where the second electrode active material is not applied. The second electrode tab 15 may be connected to an external second terminal (not shown). In some embodiments, the second electrode tab 15 may be formed by being cut to protrude to the other side (e.g., the opposite side) of the electrode assembly 10 when the second electrode plate 13 is made, or the second electrode tab 15 may protrude to the other side of the electrode assembly more than (e.g., farther than or beyond) the separator 12 without being separately cut.

In some example embodiments, the first electrode tab 14 may be located on the left side of the electrode assembly 10, and the second electrode tab 15 may be located on the right side of the electrode assembly 10. In other example embodiments, the first electrode tab 14 and the second electrode tab 15 may be located on one side of the electrode assembly 10 in the same direction.

Herein, the left and right sides are defined according to the electrode assembly 10 as oriented in FIG. 1, but the positions thereof may change when the secondary battery is rotated left and right or up and down.

The separator 12 prevents a short-circuit between the first electrode 11 and the second electrode 13 while allowing movement of lithium ions therebetween. The separator 12 may be made of, for example, a polyethylene film, a polypropylene film, a polyethylene-polypropylene film, or the like.

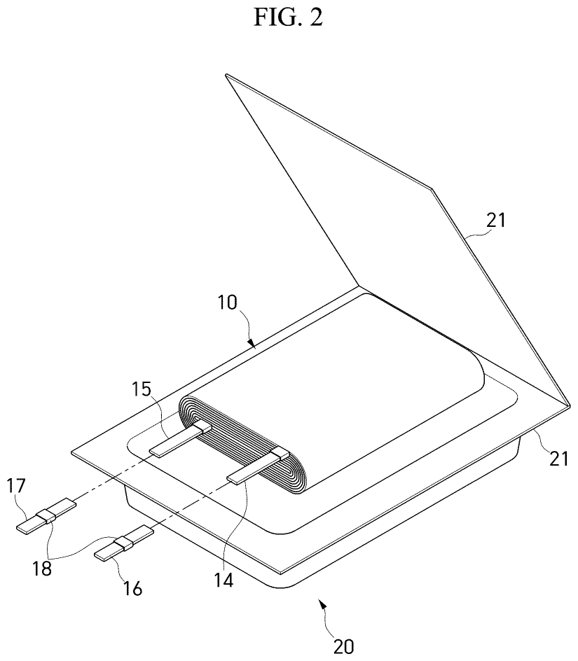

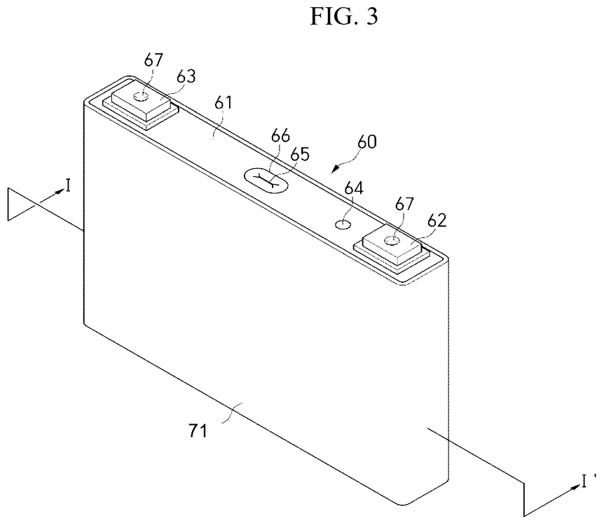

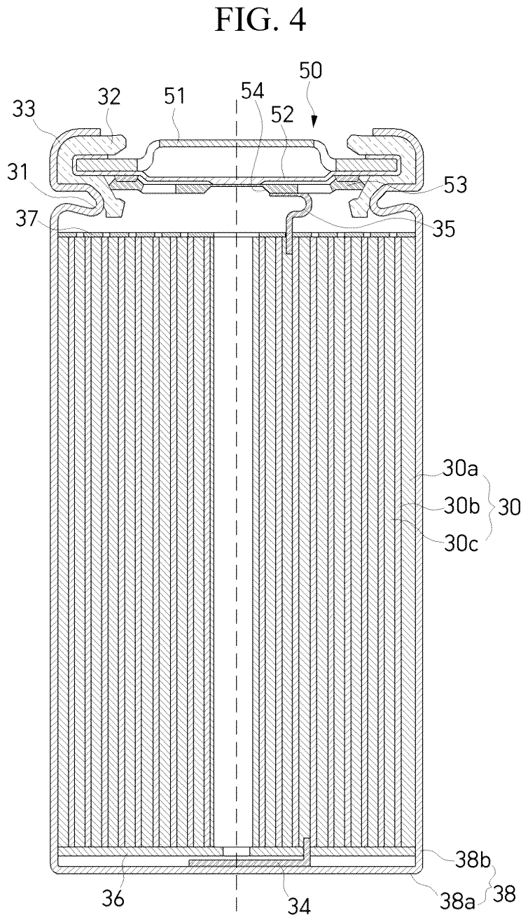

In some embodiments, the electrode assembly 10 may be accommodated in the case (not shown) along with an electrolyte. In the case of a pouch-type secondary battery, an electrode assembly 10 may be accommodated in a pouch made of flexible material in the form illustrated in FIG. 2. In the case of a cylindrical or prismatic secondary battery, an electrode assembly 10 may be accommodated in a cylindrical or prismatic metal casing in the form illustrated in FIGS. 3 and 4.

FIG. 2 schematically illustrates a pouch-type secondary battery.

The pouch-type secondary battery includes an electrode assembly 10 and a pouch 20 that accommodates the electrode assembly 10.

The electrode assembly 10 may be the same as the electrode assembly illustrated in FIG. 1. The first electrode tab 14 and the second electrode tab 15 of the electrode assembly 10 may be electrically connected to respective external first and second terminal leads 16 and 17 by welding. Each of the first terminal lead 16 and the second terminal lead 17 may be attached with a tab film 18 for insulation from the pouch 20.

The pouch 20 may be sealed by having sealing parts 21 at the edges thereof come into contact with each other with the electrode assembly 10 is accommodated in the pouch 20, in which case the sealing may be achieved with the tab film 18 interposed between the sealing parts 21. The sealing parts 21 of the pouch 20 may each be made of a thermal fusion material that has weak adhesion to metal. Thus, the pouch 20 may be fused by interposing the thin tab film 18 between the sealing parts 21.

FIG. 3 is a top perspective view of a prismatic secondary battery.

A case 71 defines an outer appearance of the prismatic secondary battery. The case 71 may be made of a conductive metal, such as aluminum, aluminum alloy, or nickel-plated steel. In addition, the case 51 provides a space for accommodating an electrode assembly therein.

A cap assembly 60 may include a cap plate 61 that covers the opening of the case 71. In some examples, the case 71 and the cap plate 61 may be made of a conductive material. Here, a first terminal 63 and a second terminal 62 may be electrically connected to respective positive and negative (or negative and positive) electrodes inside the case. The first and second terminals 63 and 62 may protrude outward from the cap plate 61.

The cap plate 61 may include an electrolyte injection port 64 and a sealing plug (or seal pin). Also, a vent 66 may be formed with a notch 65. The vent 66 is for discharging gas generated inside the secondary battery.

FIG. 4 is a cross-sectional view of a cylindrical battery. The secondary battery includes an electrode assembly 30, a case 38 accommodating the electrode assembly 30 and an electrolyte therein, a cap assembly 50 coupled to an opening of the case 38 to seal the case, and an insulating plate 37 positioned between the electrode assembly 30 and the cap assembly 50 inside the case 38.

The electrode assembly 30 may include a separator 30b and a first electrode 30c and a second electrode 30a positioned with the separator interposed therebetween and may be wound in a jelly-roll shape.

The first electrode 30c includes a first substrate and a first active material layer on the first substrate. A first lead tab 35 may extend outwardly from a first uncoated portion of the first substrate where the first active material layer is not provided. The first lead tab 35 may be electrically connected to the cap assembly 50.

The second electrode 30a includes a second substrate and a second active material layer on the second substrate. A second lead tab 34 may extend outwardly from a second uncoated portion of the second substrate where the second active material layer is not provided. The second lead tab 34 may be electrically connected to the case 38. The first lead tab 35 and the second lead tab 34 may extend in opposite directions.

The first electrode 30c may act as a positive electrode. In such an embodiment, the first substrate may be made of, for example, an aluminum foil, and the first active material layer may include, for example, a transition metal oxide. The second electrode 30a may act as a negative electrode. In such an embodiment, the second substrate may be made of, for example, a copper foil or a nickel foil, and the second active material layer may include graphite, for example.

The separator 30b prevents a short circuit between the first electrode 30c and the second electrode 30a while allowing movement of lithium ions therebetween. The separator 32b may be made of, for example, a polyethylene film, a polypropylene film, a polyethylene-polypropylene film, or the like.

The case 38 accommodates the electrode assembly 30 and, together with the cap assembly 50, forms the external appearance of the secondary battery. The case 38 may have a substantially cylindrical body portion 38b and a bottom portion 38a connected to one side (e.g., to one end) of the body portion 38b. A beading part 31 (e.g., a bead) deformed inwardly may be formed in the body portion 38b, and a crimping part 33 (e.g., a crimp) bent inwardly may be formed at an open end of the body portion 38b.

The beading part 31 can reduce or prevent movement of the electrode assembly 30 inside the case 38 and can facilitate seating of the gasket 32 and the cap assembly 50. The crimping part 33 may firmly fix the cap assembly 50 by pressing the edge of the case 38 against the gasket 32. The case 38 may be formed of, for example, iron plated with nickel.

The cap assembly 50 may be fixed to the inside of the crimping part by a gasket 32 to seal the case 38. The cap assembly 50 may include an upper cap up 51, a safety vent 52, a lower cap 53, an insulating member, and a sub plate 54. But the cap assembly 50 is not limited to such a configuration and may be modified in various ways.

The upper cap 51 may be positioned at the uppermost part of the cap assembly 50. The upper cap 51 may include a terminal part that protrudes upwardly and is connected to an external circuit. The upper cap 51 may also include an outlet for discharging gas arranged around the terminal part.

The safety vent 52 may be located under the upper cap 51. The safety vent 52 may include a protrusion part that protrudes convexly downwardly and is connected to the sub plate 54. At least one notch may be formed in the safety vent 52 around the protrusion part. When gas is generated due to overcharging or abnormal operation of the secondary battery, the protrusion part is deformed upward by the pressure and separates from the sub plate 54 while the safety vent 52 is cut (e.g., bursts or tears) along the notch. Thus, the cut safety vent 52 may prevent the secondary battery from exploding by allowing for the gas to be discharged to outside of the secondary battery.

The lower cap 53 may be below the safety vent 52. The lower cap 53 may have a first opening through which the protrusion part of the safety vent 52 is exposed and a second opening for gas discharge. The insulating member may be positioned between the safety vent 52 and the lower cap 53 to insulate the safety vent 52 and the lower cap 53.

The sub plate 54 may be under the lower cap 53. The sub plate 54 may be fixed to a lower surface of the lower cap 53 to block the first opening of the lower cap 53, and the protrusion part of the safety vent 52 may be fixed to the sub plate 54. The first lead tab 35, which extends from the electrode assembly 30, may be fixed to the sub plate 54. Accordingly, the upper cap 51, the safety vent 52, the lower cap 53, and the sub plate 54 may be electrically connected to the first electrode 30c of the electrode assembly 30.

The insulating plate 37 may be positioned to be in contact with the electrode assembly 30 below the beading part 31. The insulating plate 37 may have a tab opening through which the first lead tab 35 extends. The cap assembly 30, which is electrically connected to the first electrode 30c by the first lead tab 35, may face the electrode assembly 30 with an insulating plate 37 interposed therebetween. The cap assembly 30 may be insulated (e.g., electrically insulated) from the electrode assembly 30 by the insulating plate 37. Another insulating plate 36 may be included for insulation between the electrode assembly 30 and the bottom portion 38a of the case 38.

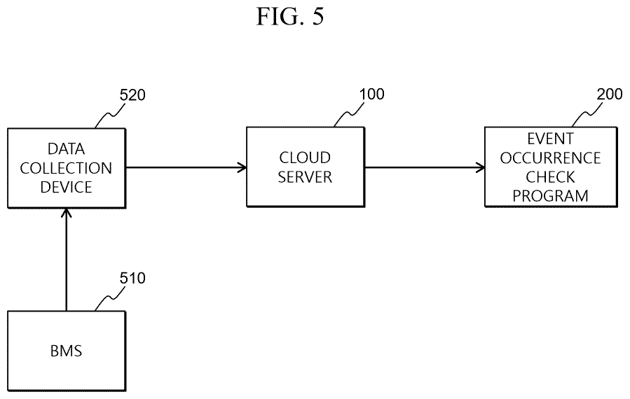

Embodiments of the present disclosure determine whether there a fire is occurring based on data transmitted to a cloud server. FIG. 5 is a conceptual diagram for explaining a method of detecting fire in ESSs using cloud services according to the present disclosure. Although the method of detecting fire in ESSs is described below as an example, the present disclosure is also applicable in other contexts. For example, the method may be used to detect fires in battery packs installed in vehicles.

Battery management systems 510 are systems that monitor battery statuses and perform diagnosis and control, communication, and protection functions. The battery management systems 510 transmit battery status data, such as voltage, current, temperature, and alarm/protection occurrence information of individual battery cells to a data collection device 520. The data collection device 520 transmits the battery status data received from the battery management systems 510 within an ESS to a cloud server 100. An event occurrence check program 200 analyzes the battery status data received from the battery management systems via the cloud server 100 to determine whether there is a fire event. The event occurrence check program 200 may be a program that runs within the cloud server 100 or a program that runs on a processor outside the cloud server 100.

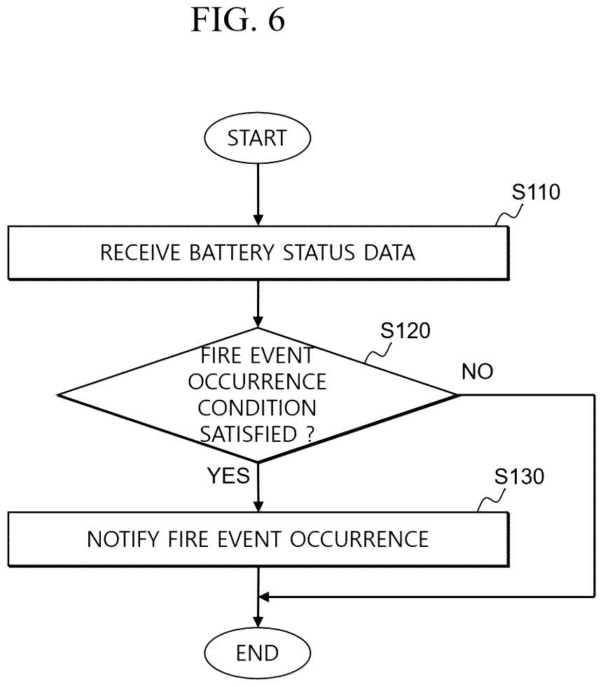

FIG. 6 is a flow diagram of a procedure for determining whether there is a fire event according to an embodiment of the present disclosure. The event occurrence check program 200 receives the battery status data from the cloud server 100 in step S110. The event occurrence check program 200 analyzes the battery status data to determine whether there is a fire in step S120. An algorithm for determining whether there is a fire will be described later. The event occurrence check program 200 indicates that a fire event has occurred when it is determined that a fire has occurred in step S130. The notification of fire event occurrence may be made by sending a text message, an email, a messenger message, etc. to a predetermined phone number, email address, messenger address, etc.

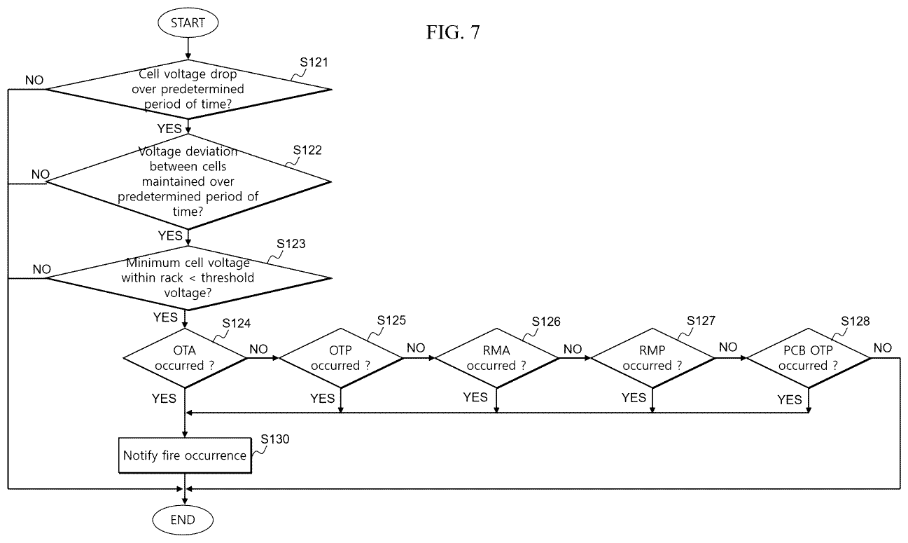

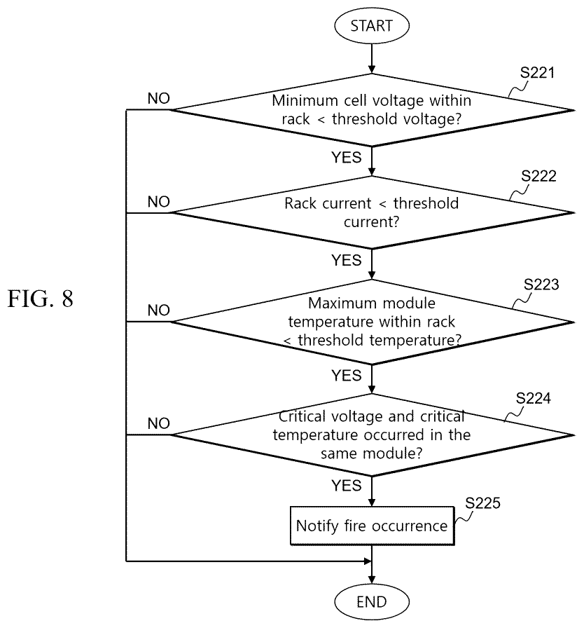

Next, several algorithms for determining whether there is a fire will be described with reference to FIGS. 7 and 8.

If a fire occurs in a battery, some or all of the following phenomena may be observed:
Cell voltage drop: in the event of fire, a cell voltage drops as the vent of the battery is opened;
Cell temperature rise: the voltage of the internal temperature sensor of the battery rises due to the fire;
Module temperature rise: the temperature of the internal module of the battery rises due to the fire; and
Communication loss: the communication with the module is lost due to explosion caused by the fire.

Since any one of these phenomena can occur in cases other than fires, determining events based on individual conditions may result in false detection. For example, if a sensor that detects the voltage of the battery fails, diagnosing a fire event by only observing the cell voltage drop may result in false detection. Therefore, the present disclosure minimizes false detection by synthesizing multiple types of data.

The present disclosure uses all or some of the following events to determine whether there is a fire:
UVP (Under Voltage Protection): a flag that occurs when cell voltage drops over a predetermined period of time;
VIMBP (Voltage Imbalance Protection): a flag that occurs when the voltage deviation between cells is maintained over a predetermined period of time;
OTA/OTP (Over Temperature Alarm/Protection): a flag that occurs when the temperature within a module is maintained above a certain value, indicating when the alarm is generated (OTA) and when the protective action is performed (OTP);
RMA/RMP (Rack Module Communication Fail Alarm/Protection): a flag that occurs when a communication error occurs between a rack BMS and a module BMS, indicating when the alarm is generated (RMA) and when the protective action is performed (RMP);
printed circuit board (PCB) OTP: a flag that occurs when the temperature of a module BMS PCB is maintained above a certain value;
Current<Cₜₕ: the current measured in a rack is lower than a threshold current Cₜₕ;
MIN_CV<Vₜₕ: the minimum cell voltage within a rack is lower than a threshold voltage Vₜₕ; and
MAX_T>Tₜₕ: the maximum module temperature within a rack is higher than a threshold temperature Tₜₕ.

FIG. 7 is a flow diagram illustrating a fire event occurrence determination algorithm according to an embodiment of the present disclosure. A fire is determined to have occurred when three AND conditions are satisfied and one of five OR conditions is satisfied. The three AND conditions are UVP, VIMBP, and MIN_CV<Vₜₕ. The five OR conditions are OTA, OTP, RMA, RMP, and PCB OTP. In other words, as shown in FIG. 7, a fire is determined to have occurred in the case of (UVP & VIMBP & (MIN_CV<Vₜₕ) & (OTA|OTP|RMA|RMP|PCB OTP)).

That is, if the following three AND conditions are all satisfied: the cell voltage drops over a predetermined period of time (step S121); the voltage deviation between cells is maintained over a predetermined period of time (step S122); and the minimum cell voltage within the rack is lower than a threshold voltage Vₜₕ (step S123), and one of the following five OR conditions is satisfied: the alarm that the temperature within the module has been maintained above a certain value (OTA) is generated (step S124); the protective action is performed (OTP) because the temperature within the module has been maintained above a certain value (step S125); the alarm that the communication error has occurred between the rack BMS and the module BMS (RMA) is generated (step S126); the protective action is performed (RMP) because the communication error has occurred between the rack BMS and the module BMS (step S127); and the temperature of the module BMS PCB is maintained above a certain value (PCB OTP) (step S128), then the event occurrence check program 200 determines that a fire has occurred in the ESS containing the relevant data and notifies that a fire event has occurred in that ESS (step S130).

The threshold voltage Vₜₕ may be set appropriately depending on the type and installation environment of battery cells and so on. For example, Vₜₕ may be 1 V.

In other embodiments, a fire event may be determined to have occurred even if only the three AND conditions are satisfied. That is, a method according to embodiments of the present disclosure may include only steps S121 to S123 and omit steps S124 to S128. In further embodiments, a fire event may be determined to have occurred if two of the three AND conditions and one of the OR conditions are satisfied. That is, it may be determined that a fire event has occurred in the following three cases:
(UVP & VIMBP) & (OTA|OTP|RMA|RMP|PCB OTP);
(VIMBP & (MIN_CV<Vₜₕ)) & (OTA|OTP|RMA|RMP|PCB OTP); and
(UVP & (MIN_CV<Vₜₕ)) & (OTA|OTP|RMA|RMP|PCB OTP).

Further, it may be determined that a fire event has occurred if two of the three AND conditions are satisfied. In other words, it may be determined that a fire event has occurred in the following three cases:
UVP & VIMBP;
VIMBP & (MIN_CV<Vₜₕ); and
UVP & (MIN_CV<Vₜₕ).

In some embodiments, the received data may be accumulated in the cloud and a determination factor may be used to activate/deactivate based on the change in characteristics of the data accumulated in the cloud. Also, the priority confirmation order may be adjusted depending on the trend of change in preset data in the confirmation order among determination factors.

FIG. 8 is a flow diagram of a fire event occurrence determination algorithm according to another embodiment of the present disclosure. In this embodiment, a fire is determined to have occurred when four AND conditions are satisfied. The four AND conditions are (MIN_CV<Vₜₕ) & (Current<Cₜₕ) & (MAX_T>Tₜₕ) & (MIN_CV and MAX_T measured modules are the same). In other words, if the minimum cell voltage within a rack is lower than a threshold voltage Vₜₕ (step S221), the current measured in the rack is lower than a threshold current Cₜₕ (step S222), the maximum module temperature within the rack is higher than a threshold temperature Tₜₕ (step S223), and steps S221 and S223 occur in the same module (step S224), the event occurrence check program 200 determines that a fire has occurred in the ESS containing the relevant data and outputs an indication that a fire event has occurred in that ESS (step S130).

The threshold voltage Vₜₕ, the threshold current Cₜₕ and the threshold temperature Tₜₕ may be set appropriately depending on the type and installation environment of battery cells and so on. For example, Vₜₕ may be 1 V, Cₜₕ may be 2 A, and Tₜₕmay be 40 degrees Celsius.

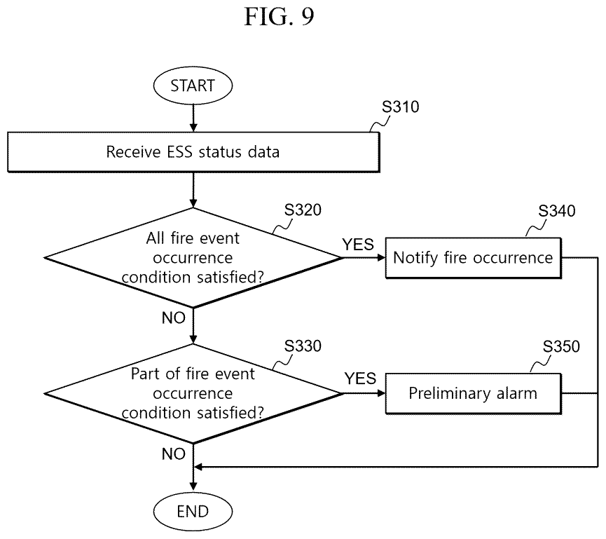

In some embodiments, the fire alarm level may vary with the event that occurs. These embodiments will be described with reference to FIG. 9.

The event occurrence check program 200 receives the battery status data received via the cloud server 100 in step S310. The event occurrence check program 200 analyzes the battery status data to determine whether all fire event occurrence conditions are satisfied in step S320. Determining whether there is a fire may use the algorithm of FIG. 7 or 8. In step S340, the event occurrence check program 200 indicates that a fire event has occurred when it is determined that a fire has occurred. The notification of fire event occurrence may be made, for example, by sending a text message, an email, a messenger message, etc., notifying that a fire has occurred in a specific ESS, to a predetermined phone number, email address, messenger address, etc. Even if not all the fire event occurrence conditions are satisfied, a preliminary alarm may be issued in step S350 if some of the specified conditions are satisfied in step S330. The preliminary alarm may be made, for example, by sending a text message, an email, a messenger message, etc., indicating that an alarm has occurred in a specific ESS, to a predetermined phone number, email address, messenger address, etc.

In embodiments, a preliminary alarm may be issued if two of the three AND conditions in the embodiment depicted in FIG. 7 are satisfied. Alternatively, a preliminary alarm may be issued if two AND conditions and one OR condition are satisfied. In other embodiments, a preliminary alarm may be issued if three of the four AND conditions in the embodiment depicted in FIG. 8 are satisfied.

Although methods for detecting fire in ESSs have been described above as an example, the present disclosure is also applicable, for example, to detecting fire in battery packs installed in vehicles. In such embodiments, it is possible to accomplish fire detection using the same algorithm by replacing the references to a rack in the above description with a battery pack.

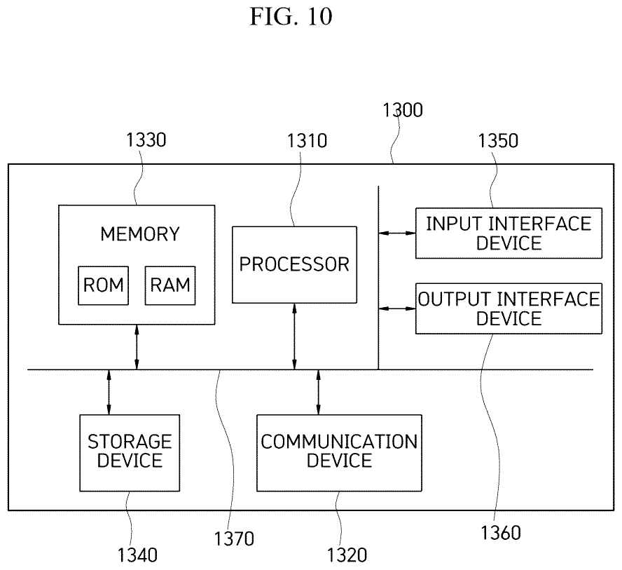

FIG. 10 is a block diagram illustrating a computer system for implementing a method according to an example embodiment of the present disclosure.

Referring to FIG. 10, the computer system 1300 may include at least one of a processor 1310, a memory 1330, an input interface device 1350, an output interface device 1360, and a storage device 1340 communicating with one another through a bus 1370. The computer system 1300 may also include a communication device 1320 coupled to a network. The communication device 1320 may transmit or receive wired signals or wireless signals. The processor 1310 may be or include a central processing unit (CPU) or a semiconductor device that executes instructions stored in the memory 1330 or in the storage device 1340. The memory 1330 and the storage device 1340 may include various types of volatile or nonvolatile storage media. For example, the memory may include a read-only memory (ROM) and a random access memory (RAM). The memory may be located inside or outside the processor and may be connected to the processor through various known means.

Embodiments of the present disclosure may be a method implemented in a computer or a non-transitory computer-readable medium storing computer-executable instructions. In such embodiments, computer-readable instructions executed by the processor may cause the computer to perform a method according to at least one aspect of the present disclosure.

Additionally, methods according to embodiments of the present disclosure may be implemented in the form of program instructions that can be executed through various computer means and recorded on a computer-readable medium. The computer-readable medium may include program instructions, data files, data structures, etc., singly or in combination. The program instructions recorded on the computer-readable medium may be specially designed and configured for embodiments of the present disclosure or may be known and usable by those skilled in the art of computer software. Computer-readable recording media may include a hardware device configured to store and perform program instructions. For example, the computer-readable recording media may be or include magnetic media such as hard disks, floppy disks, and magnetic tapes, optical media such as CD-ROMs and DVDs, magneto-optical media such as floptical disks, ROM, RAM, flash memory, etc. The program instructions may include not only machine language codes such as that generated by a compiler, but also high-level language codes that can be executed by a computer through an interpreter, etc.

The following describes materials that can be used in secondary batteries according to the present dislosure.

The positive electrode active material may include a compound (lithiated intercalation compound) that is capable of intercalating and deintercalating lithium. Specifically, at least one of a composite oxide of lithium and a metal selected from cobalt, manganese, nickel, and combinations thereof may be used.

The composite oxide may be a lithium transition metal composite oxide. Specific examples of the composite oxide include lithium nickel-based oxide, lithium cobalt-based oxide, lithium manganese-based oxide, lithium iron phosphate-based compound, cobalt-free nickel-manganese-based oxide, or a combination thereof.

As examples, the following compounds represented by any one of the following Chemical Formulas may be used. LiaA1-bXbO2-cDc (0.90≤a≤1.8, 0≤b≤0.5, and 0≤c≤0.05); LiaMn2-bXbO4-cDc (0.90≤a≤1.8, 0≤b≤0.5, and 0≤c≤0.05); LiaNi1-b-cCobXcO2-αDα (0.90≤a≤1.8, 0≤b≤0.5, 0≤c≤0.5, and 0<α<2); LiaNi1-b-cMnbXcO2-αDα (0.90≤a≤1.8, 0≤b≤0.5, 0≤c≤0.5, and 0<α<2); LiaNibCocL1dGeO2(0.90≤a≤1.8, 0≤b≤0.9, 0≤c≤0.5, 0≤d≤0.5, and 0≤e≤0.1); LiaNiGbO2(0.90≤a≤1.8 and 0.001≤b≤0.1); LiaCoGbO2(0.90≤a≤1.8 and 0.001≤b≤0.1); LiaMn1-bGbO2 (0.90≤a≤1.8 and 0.001≤b≤0.1); LiaMn2GbO4 (0.90≤a≤1.8 and 0.001≤b≤0.1); LiaMn1-gGgPO4 (0.90≤a≤1.8 and 0≤g≤0.5); Li(3−f)Fe2(PO4)3 (0≤f≤2); or LiaFePO4 (0.90≤a≤1.8). In these Chemical Formulas, A is Ni, Co, Mn, or a combination thereof; X is Al, Ni, Co, Mn, Cr, Fe, Mg, Sr, V, a rare earth element or a combination thereof; D is O, F, S, P, or a combination thereof; G is Al, Cr, Mn, Fe, Mg, La, Ce, Sr, V, or a combination thereof; and L1 is Mn, Al, or a combination thereof.

A positive electrode for a rechargeable lithium battery may include a current collector and a positive electrode active material layer on the current collector. The positive electrode active material layer may include a positive electrode active material and may further include a binder and/or a conductive material (e.g., an electrically conductive material).

An amount of the positive electrode active material may be about 90 wt % to about 99.5 wt % based on 100 wt % of the positive electrode active material layer. Amounts of the binder and the conductive material may be about 0.5 wt % to about 5 wt %, respectively, based on 100 wt % of the positive electrode active material layer.

Al may be used as the current collector. But the present disclosure is not limited thereto.

The negative electrode active material may include a material that reversibly intercalates/deintercalates lithium ions, a lithium metal, a lithium metal alloy, a material capable of doping/dedoping lithium, or a transition metal oxide.

The material that reversibly intercalates/deintercalates lithium ions may include a carbon-based negative electrode active material, such as, for example, crystalline carbon, amorphous carbon or a combination thereof. The crystalline carbon may be graphite such as non-shaped, sheet-shaped, flake-shaped, sphere-shaped, or fiber-shaped natural graphite or artificial graphite. The amorphous carbon may be a soft carbon, a hard carbon, a mesophase pitch carbonization product, calcined coke, and the like.

The material capable of doping/dedoping lithium may be a Si-based negative electrode active material or a Sn-based negative electrode active material. The Si-based negative electrode active material may include silicon, a silicon-carbon composite, SiOx (0<x<2), a Si-Q alloy and a combination thereof.

The silicon-carbon composite may be a composite of silicon and amorphous carbon. According to an embodiment, the silicon-carbon composite may be in a form of silicon particles and amorphous carbon coated on the surfaces of the silicon particles.

The silicon-carbon composite may further include crystalline carbon. For example, the silicon-carbon composite may include a core including crystalline carbon and silicon particles and an amorphous carbon coating layer on a surface of the core.

The negative electrode for a rechargeable lithium battery may include a current collector and a negative electrode active material layer on the current collector. The negative electrode active material layer may include a negative electrode active material and may further include a binder and/or a conductive material (e.g., an electrically conductive material).

For example, the negative electrode active material layer may include about 90 wt % to about 99 wt % of the negative electrode active material, about 0.5 wt % to about 5 wt % of the binder, and about 0 wt % to about 5 wt % of the conductive material.

The binder may serve to attach the negative electrode active material particles to each other and also to attach the negative electrode active material to the current collector. The binder may include a non-aqueous binder, an aqueous binder, a dry binder, or a combination thereof.

The negative current collector may include a copper foil, a nickel foil, a stainless steel foil, a titanium foil, a nickel foam, a copper foam, a polymer substrate coated with a conductive metal, or a combination thereof.

The electrolyte solution for a rechargeable lithium battery may include a non-aqueous organic solvent and a lithium salt.

The non-aqueous organic solvent may serve as a medium for transmitting ions taking part in the electrochemical reaction of a battery. The non-aqueous organic solvent may be a carbonate-based, ester-based, ether-based, ketone-based, or alcohol-based solvent, an aprotic solvent, or a combination thereof.

In addition, when using a carbonate-based solvent, a cyclic carbonate and a chain carbonate may be mixed and used.

Depending on the type of the rechargeable lithium battery, a separator may be present between the positive electrode and the negative electrode. The separator may include polyethylene, polypropylene, polyvinylidene fluoride, or a multilayer film of two or more layers thereof. The separator may include a porous substrate and a coating layer including an organic material, an inorganic material, or a combination thereof on one or both surfaces of the porous substrate.

The organic material may include a polyvinylidene fluoride-based polymer or a (meth)acrylic polymer.

The inorganic material may include inorganic particles selected from Al2O3, SiO2, TiO2, SnO2, CeO2, MgO, NiO, CaO, GaO, ZnO, ZrO2, Y2O3, SrTiO3, BaTiO3, Mg(OH)2, boehmite, and a combination thereof. But the present disclosure is not limited to these examples.

The organic material and the inorganic material may be mixed in one coating layer. In other embodiments, a coating layer including an organic material and a coating layer including an inorganic material may be stacked.

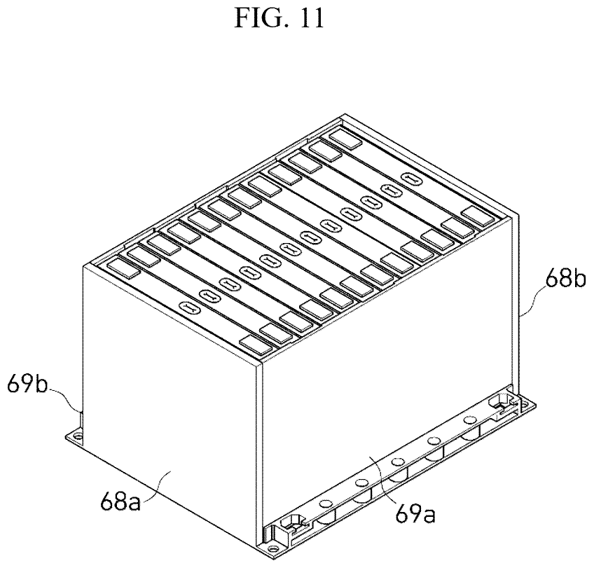

FIG. 11 is an exemplary diagram of a secondary battery module in which secondary battery cells of the present disclosure are disposed. To the increase in secondary battery capacity for driving electric vehicles, a plurality of secondary battery cells may be put into a module case of a predetermined shape and disposed and connected in a horizontal direction and/or a vertical direction to make a secondary battery module. The secondary batteries are arranged in the space formed by a pair of opposing end plates 68a, 68b and a pair of opposing side plates 69a, 69b. The arrangement of the secondary batteries can be designed in terms of the arrangement direction and number to obtain the desired voltage and current specifications.

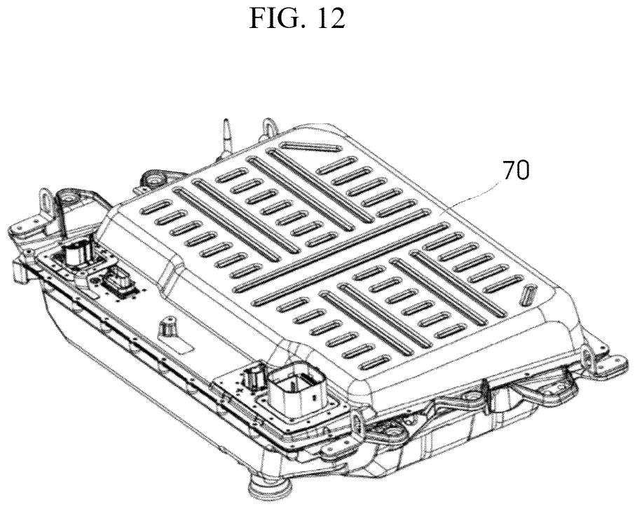

FIG. 12 illustrates a secondary battery pack 70 formed using the secondary battery module shown in FIG. 11 for an actual product (e.g., a vehicle). The secondary battery pack may be made by embedding a plurality of secondary battery modules into a pack housing designed to be mounted in the actual product. The pack housing may include fasteners and electrical outlets necessary for mounting to the product. In FIG. 12, for convenience of illustration, related elements such as bus bars for electrical connection of the secondary batteries, cooling units, and external terminals are omitted.

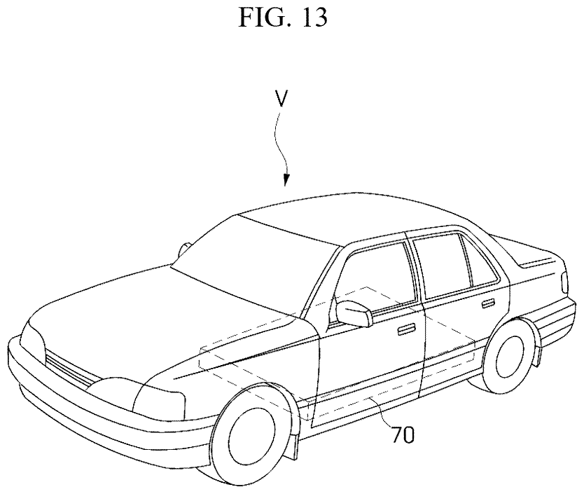

The secondary battery pack may be mounted on a vehicle. The vehicle may be, for example, an electric vehicle, a hybrid vehicle, or a plug-in hybrid vehicle. The vehicle may include a four-wheel drive or two-wheel drive vehicle. FIG. 13 shows a vehicle including the secondary battery pack shown in FIG. 12. FIG. 13 illustrates the secondary battery pack 70 according to an embodiment of the present disclosure mounted on a lower portion of a vehicle body of a vehicle. The vehicle operates by receiving power from the secondary battery pack 70 according to one embodiment of the present disclosure.

As is apparent from the above description, according to the present disclosure it is possible to detect whether a fire has occurred in an ESS or a battery pack without using a separate fire sensor in the ESS or the battery pack. Because data is received within a short period of time in the cloud system, it is possible to recognize the occurrence of fire in its early stages and allow respond accordingly. In addition, it is possible to set the conditions for determining fire occurrence in cloud data depending on the type and installation environment of batteries, thereby allowing for response to various environments and needs.

However, effects which may be obtained by the present disclosure are not limited to the aforementioned effects, and other effects not described above may be evidently understood by those skilled in the art from the following description.

Although the present disclosure has been described above with respect to embodiments, the present disclosure is not limited those embodiments. Various modifications and variations can be made by those skilled in the art within the spirit of the present disclosure.

What is claimed is:

1. A method of detecting fire in energy storage systems, the method comprising:
receiving battery status data from battery management systems via a server; and
analyzing the received battery status data to determine whether a fire occurs in one of the energy storage systems.

2. The method as claimed in claim 1, wherein, in the analyzing the received battery status data, the fire is determined to occur if a cell voltage drops over a predetermined period of time, a voltage deviation between cells is maintained over a predetermined period of time, and a minimum cell voltage within a rack is lower than a threshold voltage.

3. The method as claimed in claim 1, wherein, in the analyzing the received battery status data, the fire is determined to occur if the following three conditions are all satisfied: (i) a cell voltage drops over a predetermined period of time; (ii) a voltage deviation between cells is maintained over a predetermined period of time; and (iii) a minimum cell voltage within a rack is lower than a threshold voltage, and at least one of the following five conditions is satisfied: (i) an alarm that an in-module temperature is maintained above a certain value is generated; (ii) a protective action is performed because the in-module temperature is maintained above the certain value; (iii) an alarm that a communication error occurs between a rack battery management system and a module battery management system is generated; (iv) a protective action is performed because the communication error occurs between the rack battery management system and the module battery management system; and (v) a module battery management system printed circuit board temperature is maintained above a certain value.

4. The method as claimed in claim 1, wherein, in the analyzing the received battery status data, the fire is determined to occur if at least two of the following three conditions are satisfied: (i) a cell voltage drops over a predetermined period of time, (ii) a voltage deviation between cells is maintained over a predetermined period of time, and (iii) a minimum cell voltage within a rack is lower than a threshold voltage.

5. The method as claimed in claim 1, wherein, in the analyzing the received battery status data, the fire is determined to occur if at least two of the following three conditions are satisfied: (i) a cell voltage drops over a predetermined period of time; (ii) a voltage deviation between cells is maintained over a predetermined period of time; (iii) a minimum cell voltage within a rack is lower than a threshold voltage; and (iv) at least one of the following five conditions is satisfied: (iv-i) an alarm that an in-module temperature is maintained above a certain value is generated; (iv-ii) a protective action is performed because the in-module temperature is maintained above the certain value; (iv-iii) an alarm that a communication error occurs between a rack battery management system and a module battery management system is generated; (iv-iv) a protective action is performed because the communication error occurs between the rack battery management system and the module battery management system; and (iv-v) a module battery management system printed circuit board temperature is maintained above a certain value.

6. The method as claimed in claim 1, wherein, in the analyzing the received battery status data, the fire is determined to occur if a minimum cell voltage within a rack is lower than a threshold voltage, a current measured in the rack is lower than a threshold current, a maximum module temperature within the rack is higher than a threshold temperature, and the minimum cell voltage within the rack being lower than the threshold voltage and the maximum module temperature within the rack being higher than the threshold temperature occur in one module.

7. The method as claimed in claim 1, further comprising providing a notification that a fire event occurs when it is determined that the fire occurs.

8. The method as claimed in claim 1, wherein the server is a cloud server.

9. A method of detecting fire in battery packs, the method comprising:
receiving battery status data from battery management systems via a server; and
analyzing the received battery status data to determine whether a fire occurs in one of the battery packs.

10. The method as claimed in claim 9, wherein, in the analyzing the received battery status data, the fire is determined to occur if a cell voltage drops over a predetermined period of time, a voltage deviation between cells is maintained over a predetermined period of time, and a minimum cell voltage within a battery pack is lower than a threshold voltage.

11. The method as claimed in claim 9, wherein, in the analyzing the received battery status data, the fire is determined to occur if the following three conditions are all satisfied: (i) a cell voltage drops over a predetermined period of time; (ii) a voltage deviation between cells is maintained over a predetermined period of time; and (iii) a minimum cell voltage within a battery pack is lower than a threshold voltage, and at least one of the following five conditions is satisfied: (i) an alarm that an in-module temperature is maintained above a certain value is generated;
(ii) a protective action is performed because the in-module temperature is maintained above the certain value; (iii) an alarm that a communication error occurs between a battery pack battery management system and a module battery management system is generated; (iv) a protective action is performed because the communication error occurs between the battery pack battery management system and the module battery management system; and (v) a module battery management system printed circuit board temperature is maintained above a certain value.

12. The method as claimed in claim 9, wherein, in the analyzing the received battery status data, the fire is determined to occur if at least two of the following three conditions are satisfied: (i) a cell voltage drops over a predetermined period of time, (ii) a voltage deviation between cells is maintained over a predetermined period of time, and (iii) a minimum cell voltage within a battery pack is lower than a threshold voltage.

13. The method as claimed in claim 9, wherein, in the analyzing the received battery status data, the fire is determined to occur if at least two of the following three conditions are satisfied: (i) a cell voltage drops over a predetermined period of time; (ii) a voltage deviation between cells is maintained over a predetermined period of time; (iii) a minimum cell voltage within a battery pack is lower than a threshold voltage; and (iv) at least one of the following five conditions is satisfied: (iv-i) an alarm that an in-module temperature is maintained above a certain value is generated; (iv-ii) a protective action is performed because the in-module temperature is maintained above the certain value; (iv-iii) an alarm that a communication error occurs between a battery pack battery management system and a module battery management system is generated; (iv-iv) a protective action is performed because the communication error occurs between the battery pack battery management system and the module battery management system; and (iv-v) a module battery management system printed circuit board temperature is maintained above a certain value.

14. The method as claimed in claim 9, wherein, in the analyzing the received battery status data, it is determined that the fire occurs if a minimum cell voltage within a battery pack is lower than a threshold voltage, a current measured in the battery pack is lower than a threshold current, a maximum module temperature within the battery pack is higher than a threshold temperature, and the minimum cell voltage within the battery pack being lower than the threshold voltage and the maximum module temperature within the battery pack being higher than the threshold temperature occur in one module.

15. The method as claimed in claim 9, further comprising providing a notification that a fire event occurs when it is determined that the fire occurs.

16. The method as claimed in claim 9, wherein the server is a cloud server.
